(19) United States
(12) Patent Application Publication
(10) Pub. No.: US 2010/0200891 A1
(43) Pub. Date: Aug. 12, 2010

(54) LED STRUCTURE

(75) Inventors: Liann-Be Chang, Tao-Yuan (TW); Chin-Huai Young, Tao-Yuan (TW); Yu-Lin Lee, Tao-Yuan (TW)

Correspondence Address: NIKOLAI & MERSEREAU, P.A., 900 SECOND AVENUE SOUTH, SUITE 820, MINNEAPOLIS, MN, 55402, US

(73) Assignee: CHANG GUNG UNIVERSITY, Tao-Yuan (TW)

(21) Appl. No.: 12/762,635

(22) Filed: Apr. 19, 2010

Related U.S. Application Data
(63) Continuation-in-part of application No. 11/852,461, filed on Sep. 10, 2007.

(51) Int. Cl. H01L 33/44

(52) U.S. Cl. 257/100; 257/E33.06

(57) ABSTRACT

The present invention discloses an improved LED structure and comprises: a LED chip; a wire; a packing mask; and a photocatalytic agent. The volume of an LED is smaller so as to be convenient for installation. Compared to a conventional LED with same power, the present invention increases the total contact surface area that contacts air, so that the functions of disinfection, deodorization, and mildewproofing can be effectively achieved.

### CROSS-REFERENCE TO RELATED APPLICATION

The present application is a continuation-in-part of U.S. patent application Ser. No. 11/852,461, filed on Sep. 10, 2007, titled LED Structure, listing Liann-Be Chang, Chin-Huai Young and Yu-Lin Lee as inventors. That application is deemed to be incorporated herein in its entirety.

### BACKGROUND OF THE INVENTION

1. Field of the Invention

The present invention relates generally to an improved LED structure with a photocatalytic agent. More particularly it involves an LED structure that causes a reaction of the photocatalytic agent that achieves disinfection, deodorization, and mildewproofing functions.

2. Description of the Prior Art

A photocatalytic agent is a catalyst that is related to light and transformed by light energy, such transformation is a sort of chemistry. As a matter of fact, titanium dioxide (TiO₂) is one catalyst that achieves the transformation. Titanium dioxide itself is an activator with the characteristics of hyper oxidation and stability. A photocatalytic agent such as titanium dioxide is powerful enough to

A photocatalyst that promotes photosynthesis similar to a plant's photosynthesis is produced after titanium dioxide absorbs ultraviolet ray from sunlight or a conventional LED. The oxidation from the photocatalyst easily reduces germs in air by 99.997%.

The photocatalytic agent of the invention performs the three functions of disinfection, deodorization, and mildewproof, which are described as below:
1. Disinfection: Germs in water in air that contacts a surface treated by the photocatalytic agent and activated by ultraviolet rays, air can easily be removed due to oxidation.
2. Deodorization: Sources of odors include ammonia, hydrogen sulphide, methyl mercaptide, formaldehyde, etc. Titanium dioxide has the capability to oxidize the source that is greater than ammonia, and a capability of adsorption that is better than activated carbon related to reducing germs. While such substances exist under the circumstance of general light sources. However, titanium dioxide is capable of easily removing hydrogen sulphide, sulfur dioxide, etc. of a cigarette. Materials such as hydrogen sulphide, sulfur dioxide, and the like are known carcinogens.
3. Mildewproofing: Mildew is formed on a surface by mold. The photocatalytic agent can solve the problem very easily, such as by

According to aforesaid, the photocatalytic agent has the functions of disinfection, deodorization, and mildewproofing, but so far in the art it has not been disclosed in conventional LEDs. The total contact surface area of a conventional LED is smaller than an improved LED structure as the proposed LED assembly. The inventor has developed an improved LED structure to solve the shortcomings in the prior art.

### SUMMARY OF THE INVENTION

Presently the photocatalytic agent is only applied to conventional light bulbs. And the total contact surface area of a conventional LED is smaller than an improved LED structure as an LED assembly, which can have a plurality of LEDs. As the general purpose of the conventional LED is solid state lighting, the surface area of a conventional LED contacting air is very limited, and the corresponding oxidation capability from the conventional LED is limited and less than the desired amount of disinfection, deodorization, and mildewproofing.

The main objective of the present invention is to provide an improved LED structure, not only for solid state light but also for disinfection, deodorization, and mildewproofing functions. Moreover,

The volume of an LED is smaller so as to be convenient light bulbs to install. Comparing the present invention to a conventional LED with same size, the present invention can increase in the total contact surface area in contact with air, so that the functions of disinfection, deodorization, and mildewproofing can be effectively achieved.

Other and further features, advantages, and benefits of the invention will become apparent in the following description taken in conjunction with the following drawings. It is to be understood that the foregoing general description and following detailed description are exemplary and explanatory but are not to be restrictive of the invention. The accompanying drawings are

### BRIEF DESCRIPTION OF THE DRAWINGS

The objects, spirits, and advantages of the preferred embodiments of the present invention will be readily understood by the accompanying drawings and detailed descriptions, wherein:

FIG. 1 illustrates a schematic 3-D view of the preferred embodiment of the present invention;

FIG. 2 illustrates a schematic side view of the preferred embodiment of the present invention;

FIG. 2A illustrates a schematic top view of the preferred embodiment of the present invention;

FIG. 3 illustrates a schematic view of a chain reaction of a photocatalytic agent of the present invention;

FIG. 4 illustrates a schematic view of a broken-line graph of ultraviolet and NOₓ; FIG. 5 illustrates a schematic view of a broken-line graph of a recovering rate while eliminating NOₓ;

FIG. 6 illustrates a schematic view of a structure of nano-sized metal-oxide and binder;

FIG. 7 illustrates a schematic comparison view of larger particles and smaller particles while degrading the concentration of methylene blue; and

FIG. 8 is a table related to the concentration, duration, and total lowering rate of the present invention eliminating formaldehyde.

FIG. 9 is a bar graph comparing the efficiencies of 0-3 layers of TiO₂ for treating various bacteria.

FIG. 10 is a bar graph showing the effect of irradiating a TiO₂ coating with light of different wavelengths on bacteria removal efficiency.

### DETAILED DESCRIPTION OF THE INVENTION

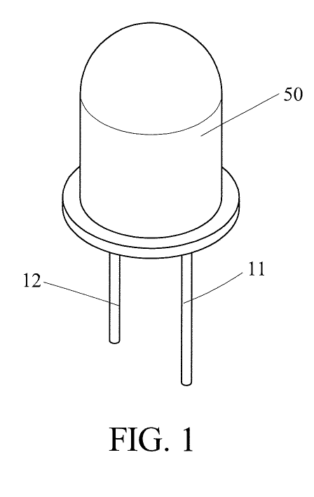

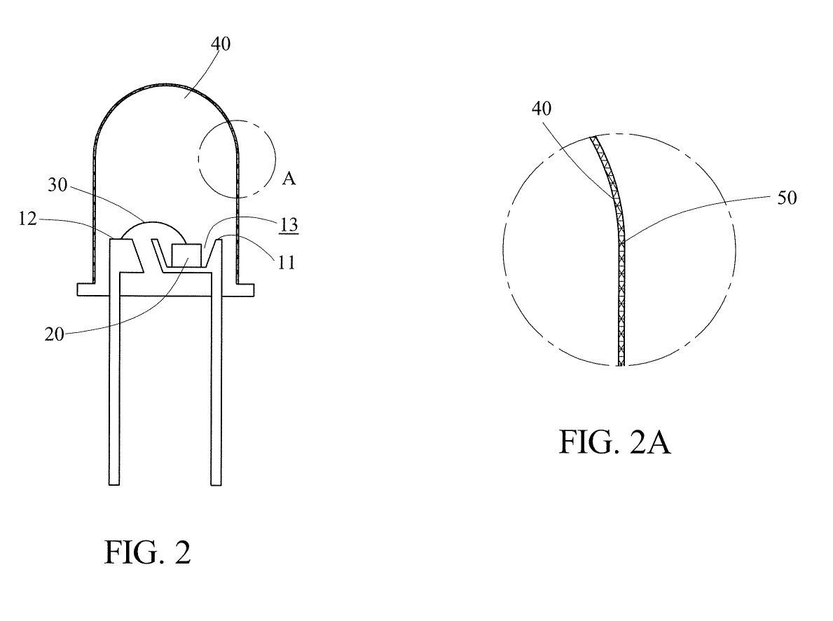

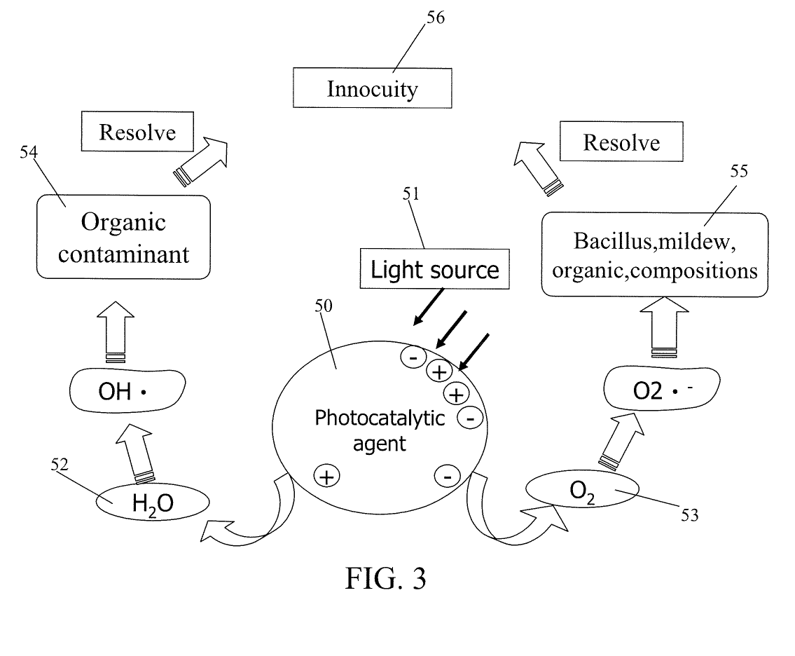

The present invention includes an improved LED structure, which has a photocatalytic agent on its surface for the purpose of disinfection, deodorization, and mildewproofing functions. With reference to FIG. 1, FIG. 2, and FIG. 2A, the improved LED structure includes:
a conductive frame having a first conductive portion 11 and a second conductive portion 12 thereon, a bowl member 13 is disposed on the first conductive portion 11 toward the conductive frame;
a LED chip 20 connected to the inner bottom surface of the bowl member 13 for electrically connecting to the first conductive portion 11;
a wire 30, having one end electrically connected to the LED chip 20, and another end electrically connected to the second conductive portion 12;
a packing mask 40 is covered on the first conductive portion 11 and the second conductive portion 12; and
a photocatalytic agent 50 is coated on the outer surface of the packing mask 40, and including a nano-sized metal-oxide so as to have the capabilities of higher oxidation, stability, and safety. The photocatalytic agent is preferably TiO₂ having a particle size in the range of between 50 and 300 nano meters.

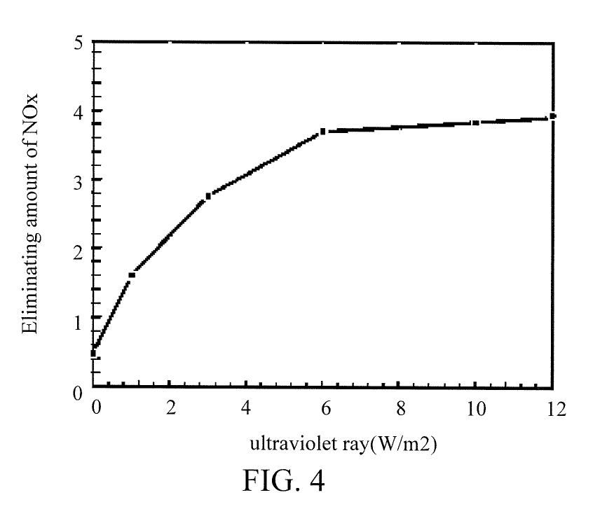

With reference to FIG. 2, FIG. 2A, and FIG. 3, the LED chip 20 projects light 51 to the photocatalytic agent 50 on the packing mask 40 and provide energy for disinfection, deodorization, and mildewproofing functions. The photocatalytic agent 50 resolves H₂O (hydrone) 52 to OH (hydroxyl ions) and O₂ 53, so that a higher oxidation is reacted in order to resolve organic contaminant 54 into innocuity 56, wherein the O₂ 53 is able to resolve organic compositions 55 as bacillus, mildew, etc. into innocuity at 56.

The volume of the LED structure of the present invention is small compared to conventional ultraviolet light bulbs, in order to

Public places of entertainment as KTV, liquor shops, etc. accommodating guests smoking cigarettes, drinking wine, etc., may have disgusting smells caused by aforesaid behaviors. Using the present invention in such places may solve the worst conditions; and, moreover, the present invention can be in the form of Christmas lights, which beautify the environment as well.

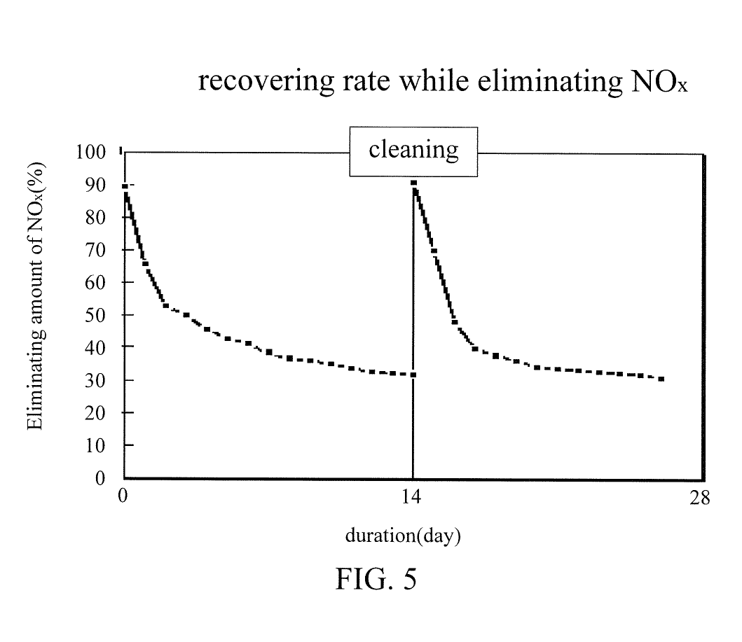

FIG. 4 illustrates a schematic view of a broken-line graph of ultraviolet and NOₓ. According to FIG. 4, the amount of NOₓ eliminated is proportional to the strength of the ultraviolet.

FIG. 5 illustrates a schematic view of a broken-line graph of a recovering rate while eliminating NOₓ. That is, from day 0 to day 14, the capability to eliminate NOₓ is gradually worse while continuously using the present invention; the capability can be recovered after cleaning the present invention, for example, the day after day 14.

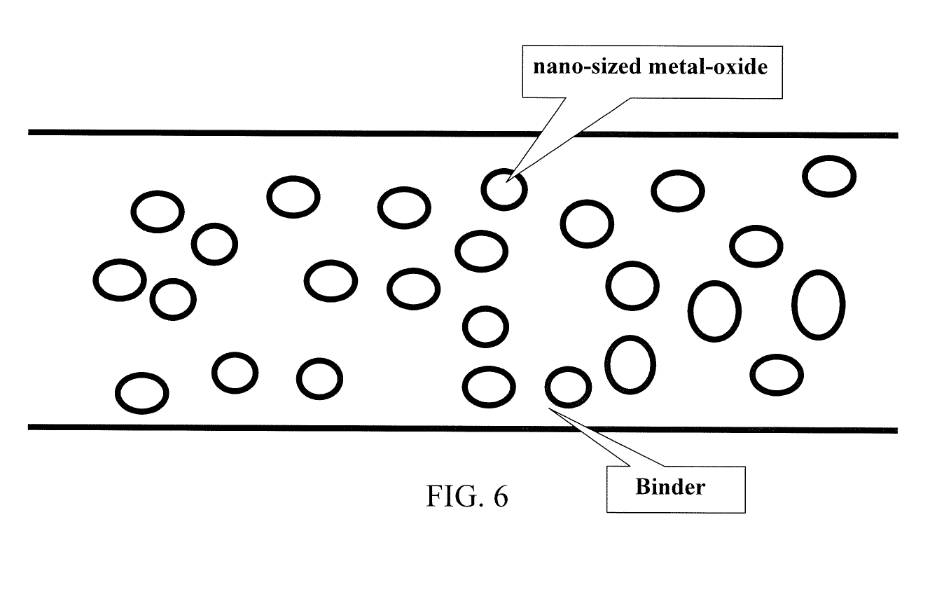

FIG. 6 illustrates a schematic view of a structure of nano-sized metal-oxide and binder.

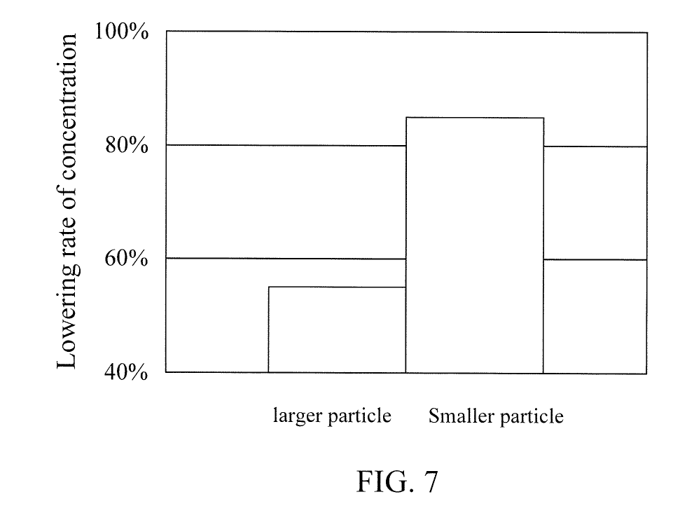

FIG. 7 illustrates a schematic comparison view of larger particles and smaller particles while degrading the concentration of methylene blue. In accordance with FIG. 7, the lowering rate of the concentration with smaller LEDs is higher than the lowering rate of the concentration with larger LEDs. That is, the total curved surface area of the smaller LEDs is larger than the total curved surface area of the larger LEDs.

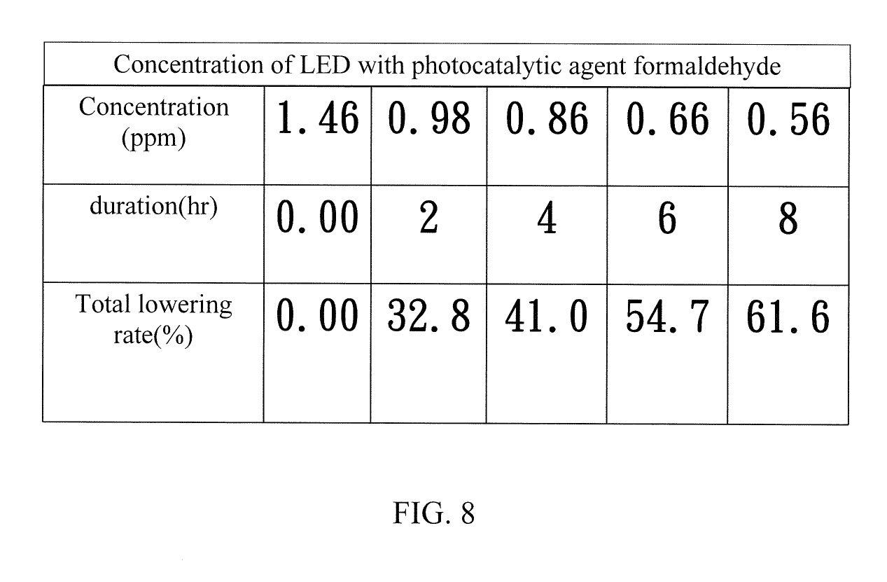

FIG. 8 is a table related to the concentration, duration, and total lowering rate of the present invention in eliminating formaldehyde. According to FIG. 8, the total lowering rate is proportional to the duration.

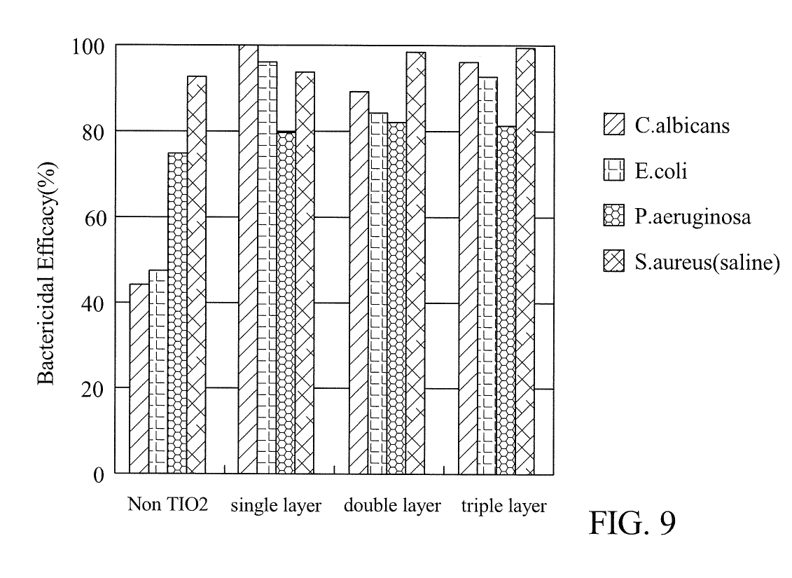

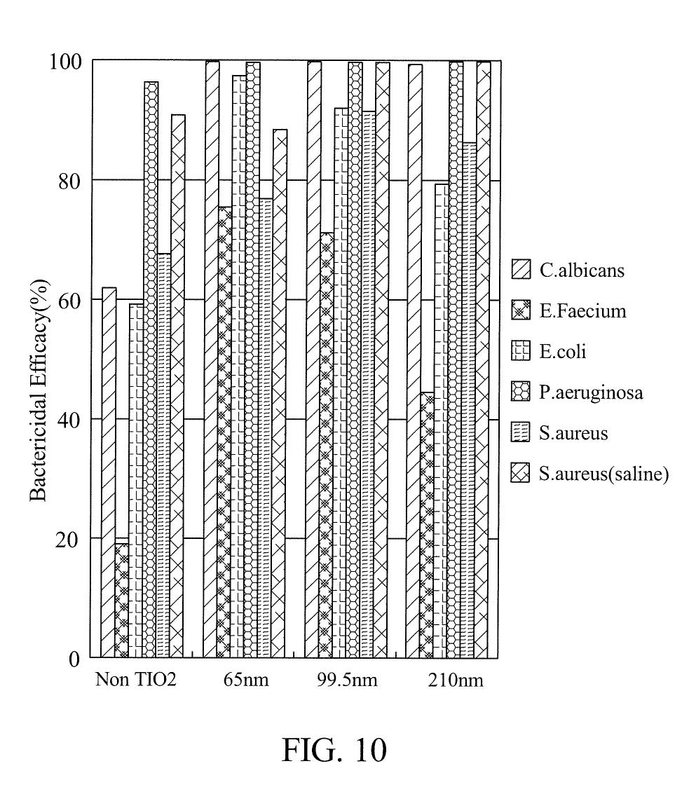

In the illustrations of FIGS. 9 and 10, the coatings is consisted of resin, solvent and nano-crystalline TiO₂ which were sprayed or spread on the surfaces and enabled for self-cleaning, deodorization and disinfection. As seen in FIGS. 10, when the surface of the TiO2 is irradiated with light with wavelengths shorter than 385 nm, free radicals are formed, causing organic compounds to decompose. Such a surface, therefore, has the functions of self-cleaning, deodorization and disinfection. The sunlight outdoors contains sufficient UV light. (Indoors the ordinary blue or UV LEDs also emit light that includes a sufficient fraction having wavelengths shorter than 385 nm).

The TiO₂-containing coatings were sprayed on glass surfaces, forming thin films when dried. Several pathogenic bacteria were suspended in glycerol solution, and then were smeared on the films and then irradiated with fluorescent light. The Li's [Ref.] results s indicated that the nano-crystalline TiO₂ containing coating have substantial bactericidal ability against Escherichia coli BCRC11634, Staphylococcus aureus BCRC10451, Pseudomonas aeruginosa BCRC12450, Enterococcus faecium BCRC10067 and Candida albicans BCRC20511.

There is a minor difference between the coatings with different thicknesses (layers), it indicates that the key point of bactericidal efficacy is not the thickness but the surface of the coating. Although the TiO₂ containing coatings are sprayed on the surface with 1, 2 or 3-layer, the surface areas of TiO₂ coating were is unchanged and the bactericidal efficacy are the same. And from FIG. 10 showing the nano particle size results, one may conclude that the total bactericidal efficacy of TiO₂ with smaller particle sizes is better. The preferred range is a particle size range is between about 50 and 300 nm.

Reference: Mr. Lien-min Li, “INFLUENCES OF PREPARATION CONDITIONS ON BACTERICIDAL EFFICACY OF TIO2 CONTAINING COATING”, Thesis for Master of Science, Department of Bioengineering, Tatung University, TAIWAN, June 2004.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. An improved LED structure comprising:
a LED chip having a first conductive portion and a second conductive portion;
a wire, having one end electrically connected to the LED chip, and another end electrically connected to the second conductive portion;
a packing mask being covered on the LED chip; and
a photocatalytic agent being coated on the outer surface of the packing mask;
wherein due to the capabilities of higher oxidation, stability, and safety of the photocatalytic agent; and the increased surface contact area, the LED assembly thus performs functions of disinfection, deodorization, and mildewproofing; wherein the photocatalytic agent comprises nano-sized metal-oxide comprising and having a particle size in the range of between 50 and 300 nano meters.
